(19) United States
(12) Patent Application Publication
(10) Pub. No.: US 2006/0281242 A1
(43) Pub. Date: Dec. 14, 2006

(54) Semiconductor device and fabrication method therefor

(76) Inventors: Naoki Takeguchi, Aizuwakamatsu-shi (JP); Yuji Mizuguchi, Aizuwakamatsu-shi (JP); Masatomi Okanishi, Aizuwakamatsu-shi (JP); Tsukasa Takamatsu, Aizuwakamatsu-shi (JP)

Correspondence Address: INGRASSIA FISHER & LORENZ, P.C., 7150 E. CAMELBACK, STE. 325, SCOTTSDALE, AZ, 85251, US

(21) Appl. No.: 11/363,792

(22) Filed: Feb. 28, 2006

Related U.S. Application Data
(63) Continuation of application No. PCT/JP05/03262, filed on Feb. 28, 2005.

(51) Int. Cl. H01L 21/8238; H01L 29/94; H01L 21/20

(52) U.S. Cl. 438/201; 438/396; 257/296

(57) ABSTRACT

A semiconductor device of the present invention includes a semiconductor substrate (10) having a bit line (14), an ONO film (16) that is provided on the semiconductor substrate (10) and has an opening (46), an interlayer insulating film (30) that is provided on the ONO film (16) and has a contact hole (40) connected to the bit line (14) and provided in the opening (46), and an insulation layer (44) provided between and separating the ONO film (16) and the contact hole (40). In forming the contact hole (40) in the interlayer insulating film (30), the ONO film (16) being provided separately from the contact hole (40) prevents the damage region from being created in the ONO film (16). This makes it possible to suppress charge loss from the trapping layer due to the damage region and provide a highly reliable semiconductor device.

### CROSS-REFERENCES TO RELATED APPLICATIONS

This is a continuation of International Application No. PCT/JP2005/003262 filed Feb. 28, 2005, which was not published in English under PCT Article 21(2).

### BACKGROUND OF THE INVENTION

1. Field of the Invention

This invention generally relates to semiconductors and fabrication methods therefor and, more particularly, to a semiconductor device having an Oxide Nitride Oxide (ONO) film and fabrication method therefor.

2. Description of the Related Art

In recent years, non-volatile memory semiconductor devices, in which data is rewritable, have been widely used. In the technical field of such non-volatile memories, developments downsizing the memory cells are being promoted to obtain higher storage capacity.

As non-volatile memories, floating-gate flash memories, in which the charge is stored in a floating gate, have been widely used. However, when the memory cell is downsized to realize high memory density in recent years, floating-gate flash memories become difficult to design. As memory cells of floating-gate flash memories are downsized, it is necessary to reduce the thickness of the tunnel oxide film. However, reducing the thickness of the tunnel oxide film increases the leakage current flowing across such film. In addition, defects introduced into the tunnel oxide film cause a problem in reliability that results in loss of the charge stored in the floating gate.

To address this problem, there have been developed flash memories having an Oxide/Nitride/Oxide (ONO) film such as a Metal Oxide Nitride Oxide Silicon (MONOS) or Silicon Oxide Nitride Oxide Silicon (SONOS). These are a type of flash memory in which the charge is stored in silicon nitride film, also known as a trapping layer, interposed between two silicon oxide films. In this type of flash memory, the charge is stored in the silicon nitride film which serves as an insulating film. Therefore, even if there is a defect in the tunnel oxide film, charge loss is minimized, unlike floating-gate type flash memories. A flash memory having an ONO film is described in, for example, Boaz Eitan et al., Electron Device Letters, Vol. 21, No. 11, pp. 543-545(2000) (hereinafter referred to as Non-Patent Document 1).

A description will next be given, with reference to FIG. 1 through FIG. 6, of a flash memory having a conventional ONO film and the fabrication method thereof (hereinafter, referred to as a conventional technique). FIG. 1 is a top view of the flash memory during the fabrication process. FIG. 2 is a cross-sectional view take along a line A-A′ shown in FIG. 1. A bit line 14 is provided in a given region of a P-type silicon semiconductor substrate 10. As the ONO film 16, there are provided a silicon oxide film serving as the tunnel oxide film, a silicon nitride film serving as the trapping layer, and another silicon oxide film serving as the top oxide film, on the semiconductor substrate 10. A polysilicon film is formed in a given region on the ONO film 16 as a word line 20 which also serves as a control gate, and a metal silicide 22 is formed on the word line 20. First sidewall layers 24 fabricated of insulating films are formed on both sides of the word line 20.

Subsequently, referring to FIG. 3, a silicon oxide film such as, for example, Boron-Phosphorus Silicated Glass (BPSG) or the like, is deposited on the transistor as an interlayer insulating film 30. In FIG. 4, the photoresist is applied over the interlayer insulating film 30 to form an opening portion 42 by a commonly used exposure technique.

In FIG. 5, the interlayer insulating film 30, the metal silicide 22, and the ONO film 16 are etched with the photoresist 32 used as a mask so that a contact hole 40 penetrates the metal silicide 22 and the ONO film 16. The photoresist 32 is then removed. FIG. 6 is a top view at this time (with the interlayer insulating film 30 not shown), FIG. 5 is a cross-sectional view taken along a line A-A′ shown in FIG. 6. Referring to FIG. 6, dotted sections in the bit line 14 denote that the bit line 14 is provided below the ONO film 16. Then, the bit line 14 is connected to an upper interconnection layer (not shown) via the contact hole 40, by a commonly used technique for forming the interconnection. Additionally, the protection film is formed and the flash memory is completed. In FIG. 5 and FIG. 6, side portions of the contact hole 40 partially serve as parts of side portions of the opening formed in the ONO film.

In the conventional technique, however, there is a problem that the stored charge is lost from the silicon nitride film serving as the trapping layer. If a certain amount of charge is lost from the trapping layer, the stored data will be lost, leading to big reliability issues for such non-volatile memories.

### SUMMARY OF THE INVENTION

It is an object of the present invention to suppress the charge loss from the trapping layer and provide highly reliable flash memories.

According to an aspect of the present invention, preferably, there is provided a semiconductor device including a semiconductor substrate having a bit line, an ONO film that is provided on the semiconductor substrate and has an opening, an interlayer insulating film that is provided on the ONO film and has a contact hole connected to the bit line and provided in the opening, and an insulation layer provided between and separating the ONO film and the contact hole. According to the present invention, in forming the contact hole in the interlayer insulating film, the ONO film being provided separately from the contact hole prevents a damage region from being created in the ONO film. This makes it possible to suppress charge loss from the trapping layer due to the damage region and provide a highly reliable semiconductor device.

According to an aspect of the present invention, preferably, there is provided a method of fabricating a semiconductor device comprising the steps of forming a bit line in a semiconductor substrate, forming an ONO film on the semiconductor substrate, forming an opening in the ONO film, forming an interlayer insulating layer on the ONO film, and forming a contact hole connected to the bit line in the interlayer insulating film and the ONO film. The step of forming the contact hole separates the ONO film from the contact hole so that an insulation film remains between the ONO film and the contact hole. According to the present invention, in forming the contact hole in the interlayer insulating film, the ONO film being provided separately from the contact hole prevents a damage region from being created in the ONO film. This makes it possible to suppress the charge loss from the trapping layer due to the damage region and provide a highly-reliable semiconductor device.

According to the present invention, in forming the contact hole in the interlayer insulating film, the ONO film is provided separately from the contact hole, preventing a damage region from being created in the ONO film. This makes it possible to suppress charge loss from the trapping layer cause by the damage region and provide a highly reliable semiconductor device.

### BRIEF DESCRIPTION OF THE DRAWINGS

FIG. 1 is a first top view illustrating a fabrication process in accordance with a conventional technique;

FIG. 2 is a first cross-sectional view illustrating the fabrication process in accordance with the conventional technique;

FIG. 3 is a second cross-sectional view illustrating the fabrication process in accordance with the conventional technique;

FIG. 4 is a third cross-sectional view illustrating the fabrication process in accordance with the conventional technique;

FIG. 5 is a fourth cross-sectional view illustrating the fabrication process in accordance with the conventional technique;

FIG. 6 is a second top view illustrating the fabrication process in accordance with the conventional technique;

FIG. 7 is a view illustrating a cause of charge loss from a trapping layer in accordance with the conventional technique;

FIG. 8 is a view illustrating that charge loss can be prevented from the trapping layer in accordance with the present invention;

FIG. 9 is a first cross-sectional view illustrating a fabrication process in accordance with a first embodiment of the present invention;

FIG. 10 is a second cross-sectional view illustrating the fabrication process in accordance with the first embodiment of the present invention;

FIG. 11 is a third cross-sectional view illustrating the fabrication process in accordance with the first embodiment of the present invention;

FIG. 12 is a top view illustrating the fabrication process in accordance with the first embodiment of the present invention;

FIG. 13 is a fourth cross-sectional view illustrating the fabrication process in accordance with the first embodiment of the present invention;

FIG. 14 is a first cross-sectional view illustrating a fabrication process in accordance with a second embodiment of the present invention;

FIG. 15 is a second cross-sectional view illustrating the fabrication process in accordance with the second embodiment of the present invention;

FIG. 16 is a third cross-sectional view illustrating the fabrication process in accordance with the second embodiment of the present invention;

FIG. 17 is a fourth cross-sectional view illustrating the fabrication process in accordance with the second embodiment of the present invention;

FIG. 18 is a top view illustrating the fabrication process in accordance with the second embodiment of the present invention;

FIG. 19 is a first cross-sectional view illustrating a fabrication process in accordance with a third embodiment of the present invention;

FIG. 20 is a second cross-sectional view illustrating the fabrication process in accordance with the third embodiment of the present invention;

FIG. 21 is a third cross-sectional view illustrating the fabrication process in accordance with the third embodiment of the present invention;

FIG. 22 is a top view illustrating the fabrication process in accordance with the third embodiment of the present invention;

FIG. 23 is a cross-sectional view illustrating a case where a contact hole 40 is misaligned from a given position during the fabrication process in accordance with the third embodiment of the present invention;

FIG. 24 is a first cross-sectional view illustrating a fabrication process in accordance with a fourth embodiment of the present invention;

FIG. 25 is a second cross-sectional view illustrating the fabrication process in accordance with the fourth embodiment of the present invention;

FIG. 26 is a third cross-sectional view illustrating the fabrication process in accordance with the fourth embodiment of the present invention;

FIG. 27 is a fourth cross-sectional view illustrating the fabrication process in accordance with the fourth embodiment of the present invention;

FIG. 28 is a first top view illustrating the fabrication process in accordance with the fourth embodiment of the present invention;

FIG. 29 is a second top view illustrating the fabrication process in accordance with the fourth embodiment of the present invention; and

FIG. 30 is a cross-sectional view illustrating a variation example in accordance with the fourth embodiment of the present invention.

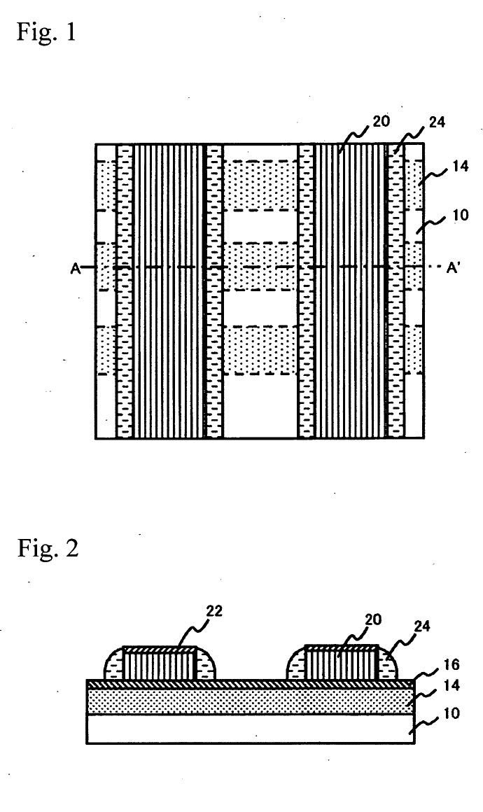

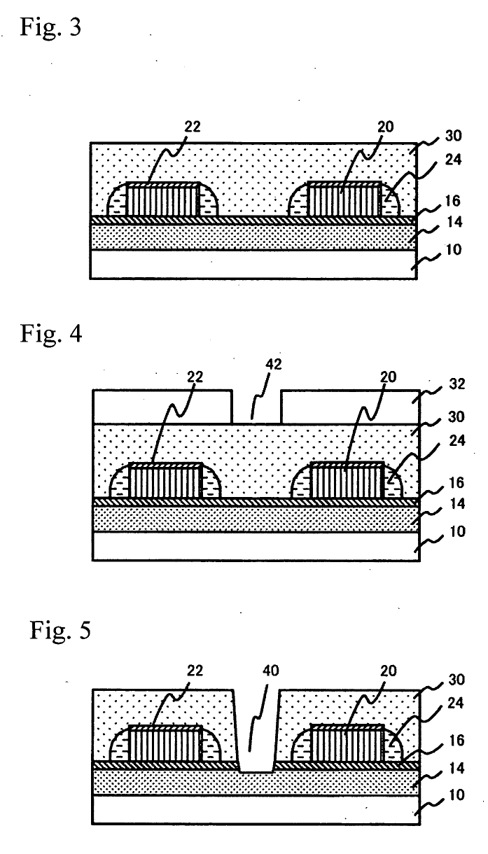

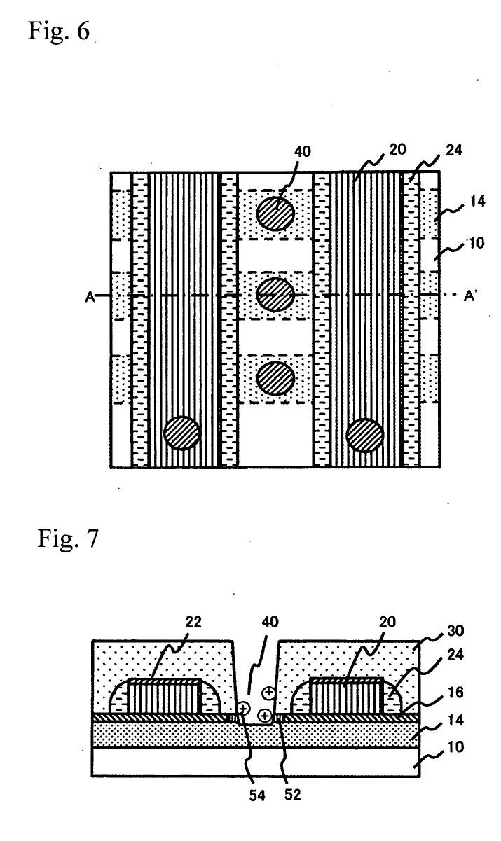

### DESCRIPTION OF THE PREFERRED EMBODIMENTS

The cause of charge loss from the trapping layer in accordance with the conventional technique will be described with reference to FIG. 7. FIG. 7 is a cross-sectional view of a fabrication process for forming the contact hole 40 that penetrates the interlayer insulating film 30 and the ONO film 16 to connect the upper interconnection layer (not shown) and the bit line. At this time, the contact hole 40 is formed by dry etching. The dry etching is performed by ions 54 in a plasma state, which chemically and physically etch the interlayer insulating film 30 and the ONO film 16. During the etch process, damage is caused to the material to be etched as well as other materials around it. The aforementioned damage includes, for example, the damage to the crystal caused by ion bombardment, the introduction of ions, and the adherence of reactive product. In accordance with the conventional technique, the contact hole 40 is formed by etching the interlayer insulating film 30 and the ONO film 16. For the interlayer insulating film 30, a thick silicon oxide film with a late dry etch rate is generally employed. For this reason, the etching is performed in a high-density plasma state at a high power so as to increase the etch rate. Therefore, the damage occurs to not only regions immediately below the contact holes but also to the side faces thereof. This results in the creation of damage regions 52 in the ONO film 16 provided on the sides of the contact hole 40. The trap level includes the damage in the band gap at the damage region of the insulating film and the trap level creates the band, making it easy for the leakage current to flow. Accordingly, charge is lost from the trapping layer.

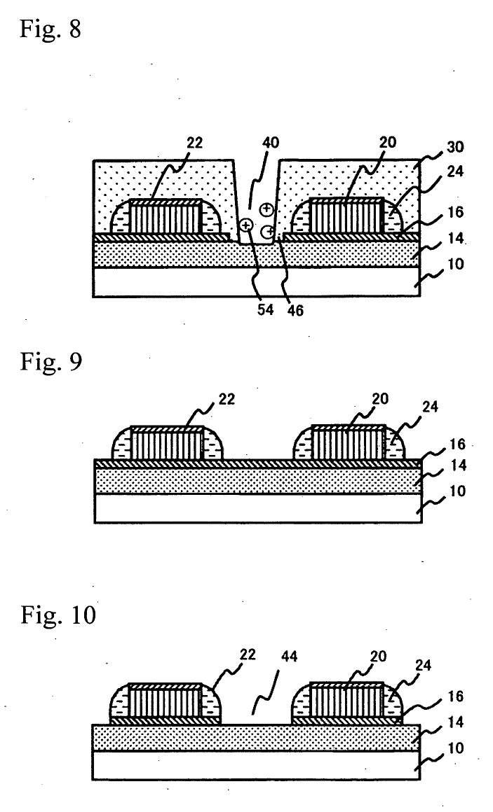

In accordance with the present invention, however, the ONO film 16 is configured to be provided separately from the contact hole 40. FIG. 8 is a view illustrating the effect of the present invention. In forming the contact hole 40 by means of dry etching, the contact hole 40 is formed in an opening 46 formed in the ONO film 16. The interlayer insulating film 30 is interposed between the ONO film 16 and the contact hole 40 in order to serve as an insulation film. This is why in accordance with the present invention no damage regions are created in the ONO film 16 during the dry etch process. Accordingly, it is possible to suppress the charge loss from the trapping layer resulting from a damage region formed in the ONO film 16.

Hereinafter, for clarification, the opening 44 denotes an opening that is common to multiple bit lines, and the opening 46 denotes an opening that is provided for each bit line.

### First Embodiment

A fabrication method in accordance with a first embodiment of the present invention will be described with reference to FIG. 9 through FIG. 13. FIG. 9 through FIG. 11 and FIG. 13 are cross-sectional views illustrating a fabrication method in accordance with the first embodiment.

FIG. 9 corresponds to FIG. 2 of the conventional technique. In accordance with commonly used techniques, for example, arsenic ions are implanted in a given region of the P-type silicon semiconductor substrate 10 (or a P-type region formed in the semiconductor substrate 10), and thermal processing is completed. By this process, the N-type bit line 14 is formed in the semiconductor substrate 10. The silicon oxide film, the silicon nitride film, and the silicon oxide film are deposited by CVD as the ONO film 16 on the semiconductor substrate 10. A polysilicon film is deposited on the ONO film 16 and a given region is removed to provide the word line 20 also serving as a control gate on the ONO film 16.

Subsequently, first sidewalls 24 are formed on the ONO film 16 in contact with sides of the word line 20 with the use of a sidewall forming method. Here, the sidewall forming method is a method in which a silicon nitride film, for example, is deposited by CVD on a laminated body having an opening and the whole surface thereof is dry etched so that the sidewall layers fabricated of silicon nitride films remain on the sides of the opening. The first sidewalls 24 are made of, for example, a silicon nitride film or a silicon oxide film. In order to reduce the resistance of the word line, a metal silicide layer 22 is provided on the word line 20. The metal silicide layer 22 is formed by, for example, sputtering cobalt and implementing a thermal process.

Next, referring to FIG. 10, the ONO film 16 is removed by etching the whole surface. Then, an opening 44 is provided in the ONO film 16. During this etch process, the high-density plasma or high power etching does not have to be employed to etch the relatively thin ONO film 16, which is different from the etch process of forming the contact hole 40. Therefore, no damage regions are formed on the sides of the ONO film or, even if a damage region is formed, only a slightly damaged region would be formed.

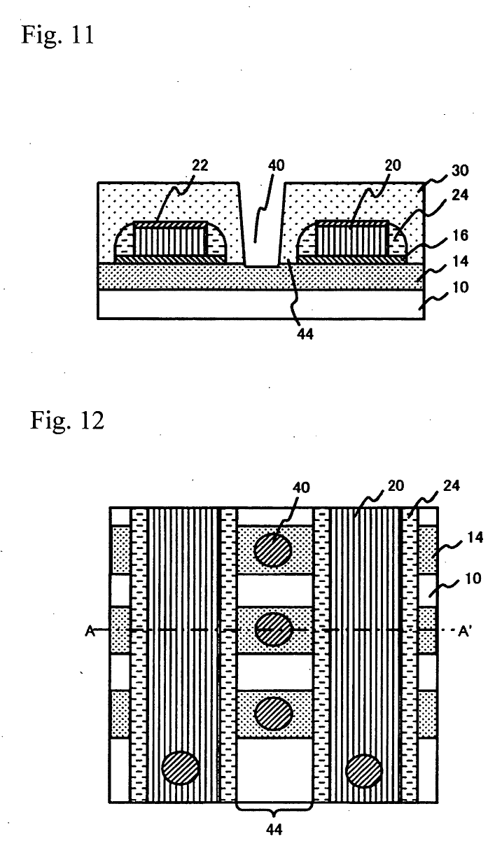

Then, referring to FIG. 11, the interlayer insulating film 30 is fabricated of a silicon oxide film such as BPSG, for example, on the ONO film 16. The interlayer insulating film 30 is dry etched with photoresist used as a mask. In this manner, the contact hole 40 is created to connect the interlayer insulating film 30 and the bit line, and the interlayer insulating film 30, serving as an insulation film, remains between the ONO film 16 and the contact hole 40. FIG. 12 is a top view at this time (wherein the interlayer insulating film 30 is not shown). FIG. 11 is a cross-sectional view taken along a line A-A′ shown in FIG. 12. In FIG. 12, solid line regions of the bit line 14 represent that the ONO film 16 is not provided on the bit line 14.

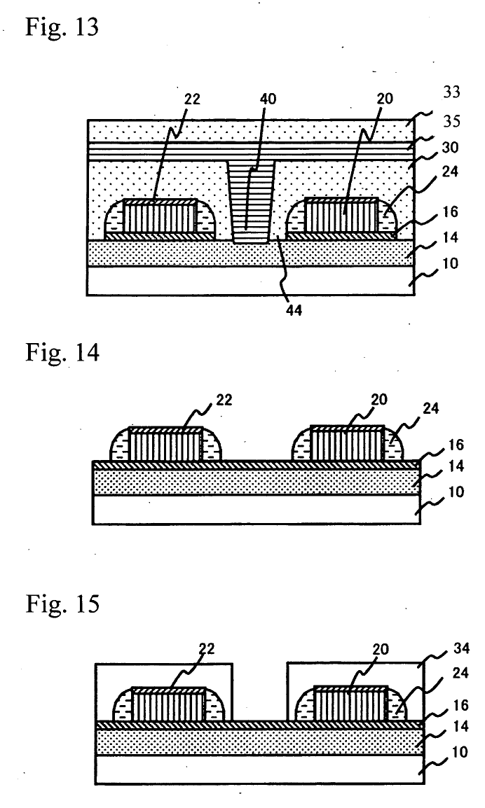

Referring to FIG. 13, by using a common interconnection-forming method, the bit line 14 is connected to an upper interconnection layer 35 via the contact hole 40. The interlayer insulating film 30 is provided above the ONO film 16, and the opening 44 includes the contact hole connected to the bit line 14. The interconnection layer 35 is fabricated of, for example, aluminum. In addition, a protection film 33 is formed and the flash memory is completed.

As illustrated in FIG. 11 and FIG. 12, the opening 44 formed in the ONO film is provided in a region other than the regions where the word line 20 and the first sidewalls 24 are provided, and the opening 44 is common to multiple bit lines 14. The ONO film 16 and the contact hole 40 are separately arranged and the interlayer insulating film serving as an insulation film is interposed therebetween. Therefore, no damage is caused on the ONO film 16 during the dry etch process of the contact hole 40. The damage caused by etching to form the opening 44 in the ONO film is extremely slight, as described above. Accordingly, charge loss from the trapping layer due to damage regions in the ONO film is suppressed, making it possible to provide a flash memory with improved reliability.

In addition, charge loss from the trapping layer caused by damage regions in the ONO film can clearly be suppressed by setting a distance between the ONO film 16 and the contact hole 40 to be far apart so that the damage in a direction to the side face may not affect the ONO film 16 during the dry etch process to form the contact hole 40.

In accordance with the first embodiment, the first sidewalls 24 are provided in contact with the sides of the word line 20 and are formed on the ONO film 16. The opening 44 is provided in the ONO film 16 by using a mask of the word line 20 and the first sidewalls 24 formed on the sides thereof. In this manner, a flash memory in accordance with the present invention can be realized by the same number of exposure steps as that of the conventional technique. That is, a flash memory in accordance with the present invention can be fabricated readily without increasing the number of fabrication man-hours.

### Second Embodiment

A second embodiment of the present invention exemplifies an opening formed in the ONO film and provided for each bit line.

A fabrication method in accordance with the second embodiment will be described, with reference to FIG. 14 through FIG. 17. FIG. 14 through FIG. 17 are cross-sectional views illustrating the fabrication method in accordance with the second embodiment. FIG. 14 corresponds to FIG. 9, and a fabrication method in accordance with the first embodiment is applied to that in FIG. 14.

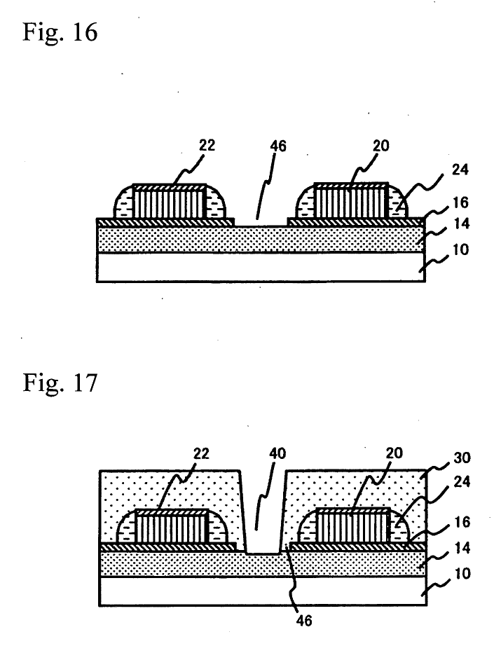

Next, referring to FIG. 15, a given opening is formed in a photoresist 34 with the use of commonly used exposure techniques. In FIG. 16, the ONO film 16 is etched with the photoresist 34 used as a mask. Then, the photoresist 34 is removed. In this manner, the opening 46 is formed in the ONO film 16. At this time, the relatively thin ONO film 16 is etched, and no damage regions are provided on the sides of the ONO film or, even if a damaged region is formed, only a slightly damaged one is formed.

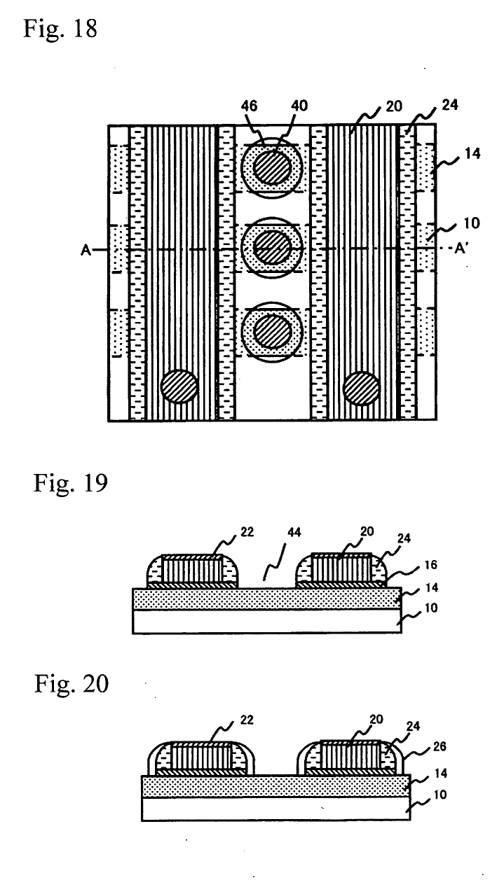

Subsequently, referring to FIG. 17, the interlayer insulating film 30 is formed and the contact hole 40 is formed by the dry etch process with photoresist used as a mask. FIG. 18 is a top view at this time (wherein the interlayer insulating film 30 is not shown). FIG. 17 is a cross-sectional view taken along a line A-A′ shown in FIG. 18. In FIG. 18, solid line regions of the bit line 14 represent that the ONO film 16 is not provided on the bit line 14, yet dotted line regions represent that the ONO film 16 is provided on the bit line. Then, the bit line 14 is connected to the upper interconnection layer (not shown) via the contact hole 40 by a commonly used interconnection-forming method. Further, the protection film (not shown) is provided and the flash memory is completed.

As shown in FIG. 17 and FIG. 18, the contact hole 40 is included in the opening 46 formed in the ONO film 16. The ONO film 16 and the contact hole 40 are separately arranged and the interlayer insulating film serving as an insulation film is interposed therebetween. Therefore, no damage is caused on the ONO film 16 during the dry etch process of the contact hole 40. The damage, if any damage there is, is extremely slight caused during the etch process to form the opening 44 in the ONO film, as described above. Accordingly, charge loss from the trapping layer due to the damage region in the ONO film is suppressed, making it possible to provide the flash memory, the reliability of which is improved.

In addition, charge loss from the trapping layer due to the damage region in the ONO film can be suppressed surely by setting a distance between the ONO film 16 and the contact hole 40 to be far apart so that damage in a direction towards the side face may not affect the ONO film 16 during the dry etch process forming the contact hole 40.

In accordance with the first embodiment, a damage layer is formed on the surface of the semiconductor substrate 10 by a dry etch process forming the opening 44 in the ONO film 16. As described above, the damage layer is more unlikely to be formed during the etch process of forming the opening 44 in the ONO film 16 than during the etch process of forming the contact hole 40. However, the damage layer is sometimes formed on the surface of the semiconductor substrate 10 provided below the opening. In this manner, the leakage current flowing across the damage layer might make leakage current flow between the bit lines 14. In accordance with the second embodiment, the opening 46 is provided only on one bit line 14 in the process of forming the opening 46 in the ONO film 16. That is to say, the opening 46 is provided on every bit line 14. In this manner, the bit lines 14 are not connected via the damage layer, making it possible to further prevent leakage current flowing between the bit lines 14.

In this manner, in accordance with the second embodiment, charge loss from the trapping layer can be suppressed and reliability is improved. In addition, it is possible to provide a flash memory in which leakage current between the bit lines can be suppressed.

### Third Embodiment

A third embodiment of the present invention exemplifies second sidewalls provided on the sides of the opening formed in the ONO film.

A fabrication method in accordance with the third embodiment will be described, with reference to FIG. 19 through FIG. 22. FIG. 19 through FIG. 21 are cross-sectional views illustrating the fabrication method in accordance with the third embodiment. FIG. 19 corresponds to FIG. 10, and the fabrication process up to this point is same as that described above in accordance with the first embodiment.

Then, referring to FIG. 20, second sidewalls 26 are provided on the sides of the first sidewalls 24, with the use of a sidewall forming method. A silicon nitride film, for example, is used for the second sidewalls 26.

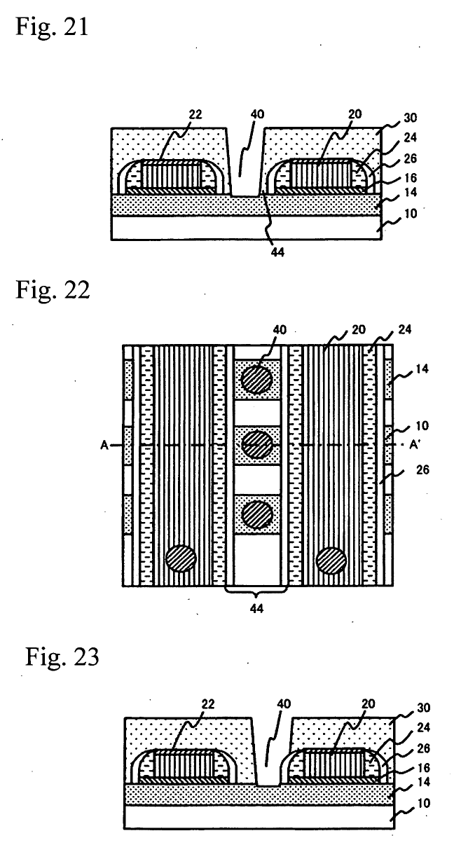

Subsequently, referring to FIG. 21, the interlayer insulating film 30 is formed, and the contact hole 40 is formed by a dry etch process with resist used as a mask. FIG. 22 is a top view at this time (wherein the interlayer insulating film 30 is not shown). FIG. 21 is a cross-sectional view taken along a line A-A′. In FIG. 22, solid-line regions of the bit line 14 represent that the ONO film 16 is not provided on the bit line 14. Then, by using a commonly used interconnection-forming method, the bit line 14 is connected to the upper interconnection layer (not shown) via the contact hole 40. In addition, the protection film (not shown) is formed and the flash memory is completed.

In accordance with the first embodiment, when the distance between the word lines 20 is reduced for downsizing, problems arise. For example, when the distance between the bit line 14 and the contact hole 40 is reduced, it can be thought that the contact hole 40 is misaligned from a given position and contacts the ONO film 16 when forming the contact hole 40. In this case, a damage region is formed in the ONO film 16 while the contact hole 40 is being formed, leading to charge loss from the trapping layer. To prevent this, if the overlapping margin of the bit line 14 and the contact hole 40 are secured for the exposure, it becomes difficult to downsize the memory cell.

In accordance with the third embodiment, the second sidewalls 26 are provided on the sides of the opening 44 formed in the ONO film 16. The second sidewalls 26 and the silicon oxide film of the interlayer insulating film 30 can be selectively etched at the time of dry etching the contact hole 40 by employing the silicon nitride film for the second sidewall 26. In this manner, the contact hole 40 is included in the opening 44 formed in the ONO film 16, even if the contact hole 40 is misaligned from a given position, as shown in FIG. 23. The ONO film 16 and the contact hole 40 are separately provided, and the interlayer insulating film 30 serving as an insulation film and the second sidewalls 26 are interposed therebetween. Therefore, no damage is caused to the ONO film 16 while the contact hole 40 is being dry etched. In this manner, it is clearly possible to prevent damage caused by dry etching while forming the contact hole 40 from affecting the ONO film 16. The overlapping margin of the bit line 14 and the contact hole 40 can be reduced for the exposure, enabling the memory cell to be downsized.

In addition, charge loss from the trapping layer caused by the damage region in the ONO film can clearly be suppressed by setting the thickness of the second sidewalls 26 to be far apart so that damage to the side face may not affect the ONO film 16 during the dry etch process forming the contact hole 40.

As described above, in accordance with the third embodiment, it is surely possible to prevent charge loss from the trapping layer, further improve the reliability, and provide a flash memory in which memory cells can be downsized.

The formation of the second sidewalls 26 on the sides of the opening 44 formed in the ONO film 16, in accordance with the third embodiment, is applicable for a case where the opening formed in the ONO film 16 is provided on every bit line as exemplified in the second embodiment. Also, in this case, the same effect as that in accordance with the third embodiment is obtainable.

### Fourth Embodiment

A fourth embodiment exemplifies a trench isolation region provided in the opening formed in the ONO film and interposed between the bit lines. This makes it possible to suppress leakage current between the bit lines and provide architecture suitable for downsizing.

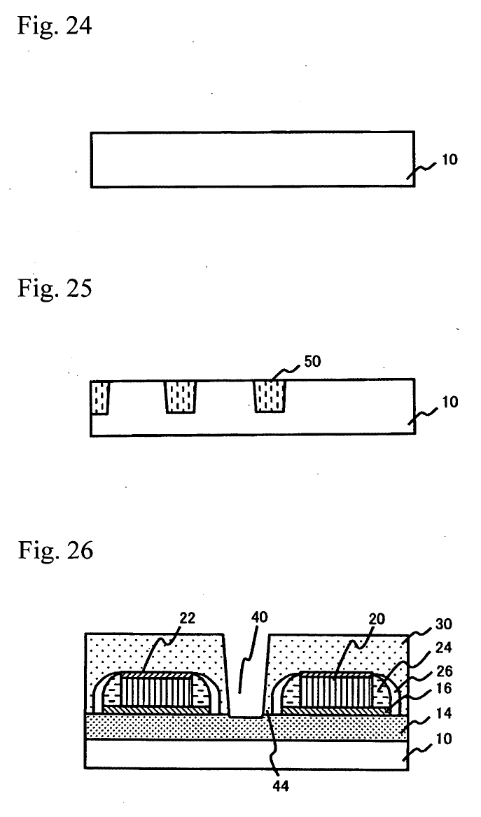

A fabrication method in accordance with the fourth embodiment will be described, with reference to FIG. 24 through FIG. 29. FIG. 24 through FIG. 29 are cross-sectional views illustrating the fabrication method in accordance with the fourth embodiment.

First, trench isolation regions 50 are formed in given regions of the P-type semiconductor substrate 10, with a commonly used Shallow Trench Isolation (STI) process. The trench isolation region is a region in which a groove (trench) portion is formed in the semiconductor substrate 10 and the silicon oxide film is formed and buried in the groove portion. The silicon oxide film is formed after the semiconductor is removed, thus enabling the leakage current to be suppressed. The trench isolation region 50 is formed, for example, in the following method. Given regions of the semiconductor substrate 10 are etched by a dry etch process to form the groove portion. Then, the silicon oxide film is deposited on the whole surface by a thermal oxidation process or CVD. Planarization is implemented by a Chemical Mechanical Polish (CMP) method or selective etching. In this manner, the silicon oxide film is buried into the groove portion and the trench isolation region is formed.

FIG. 28 is a top view subsequent to the formation of the trench isolation regions 50. FIG. 24 is a cross-sectional view taken along a line A-A′ of FIG. 28. FIG. 25 is a cross-sectional view taken along a line B-B′ of FIG. 28. The trench isolation regions 50 are interposed between the adjacently arranged bit lines 14, and are provided in the opening 44 formed in the ONO film 16 in the semiconductor substrate 10. The trench isolation regions 50 are formed simultaneously with the formation of the trench isolation regions in the peripheral circuit region, thereby enabling the fabrication process to be simplified.

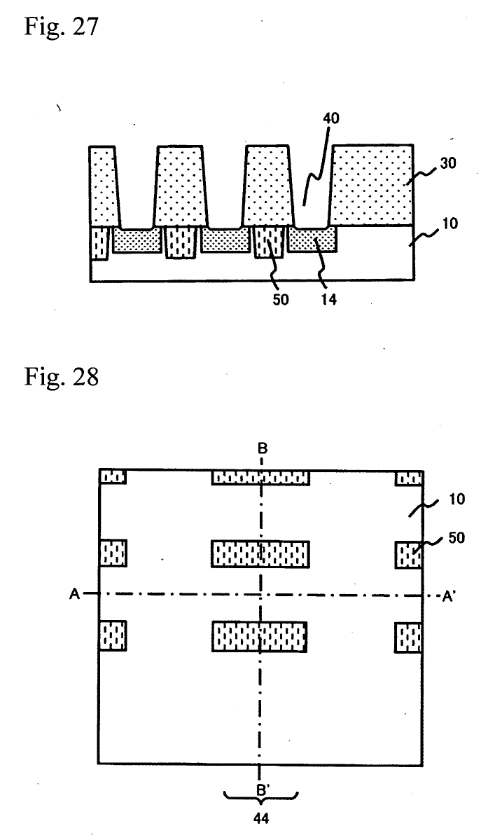

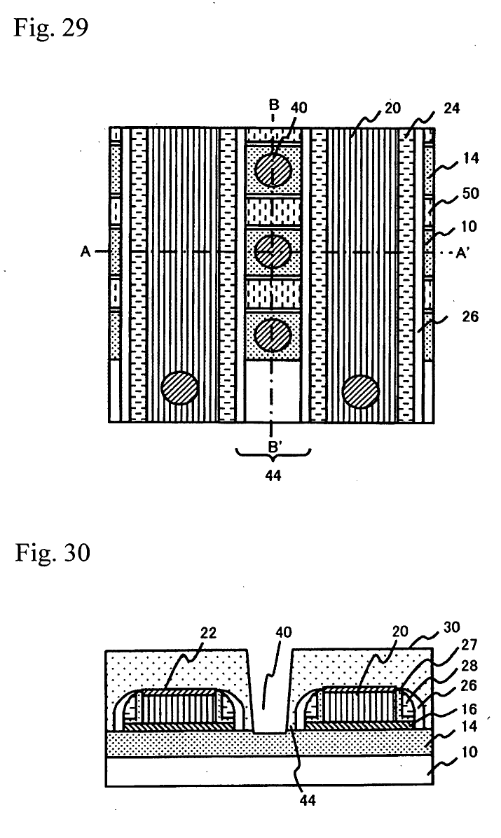

Next, fabrication processes are implemented in the same manner as shown in FIG. 19 through FIG. 21 in accordance with the third embodiment. By this, the opening 44 and the contact hole 40 are formed in the ONO film 16. FIG. 29 is a top view (wherein the interlayer insulating film 30 is not shown). FIG. 26 and FIG. 27 are cross-sectional views taken along lines A-A′ and B-B′, respectively, shown in FIG. 29. In FIG. 29, the solid-line regions of the bit line 14 represent that the ONO film 16 is not provided on the bit line 14. The trench isolation regions 50 are interposed between the bit lines 14 and are provided in the openings 44 in the ONO film 16. Subsequently, the bit line 14 is connected to the upper interconnection layer (not shown) via the contact hole 40, by a commonly used forming method. In addition, the protection film (not shown) is formed and the flash memory is completed.

As shown in FIG. 26, FIG. 27, and FIG. 29, the ONO film 16 and the contact hole 40 are separately provided. Also, even if the contact hole 40 and the opening 44 are overlapped in a misaligned manner, the second sidewalls 26 do not cause damage to the ONO film 16 at the time of dry etching the contact hole 40. In addition, extremely slight damage might be caused by the etching forming the opening 44 of the ONO film, as described-above. Therefore, charge loss due to the damage region in the ONO film can be suppressed in the trapping layer.

In accordance with the first and third embodiments, the damage layer is created on the surface of the semiconductor substrate 10 by dry etching forming the opening 44 in the ONO film 16. There is a problem in that leakage current flowing in the damage layer makes leakage current flow between the bit lines. Further, in accordance with the second embodiment, two exposure processes are needed for forming the opening 44 in the ONO film 16 and for forming the contact hole 40. With two exposure processes, another problem arises in that the overlapping margin is provided in each of the two exposure processes, thus making it difficult to downsize the distance between the word lines and making the fabrication process complicated.

In accordance with the fourth embodiment, trench isolation regions are interposed between the bit lines 14 and are provided in the openings 44 in the ONO film 16 in the semiconductor substrate 10 for element isolation. For this reason, it is possible to prevent leakage current flowing between the bit lines 14, which may result from a damage layer introduced into the semiconductor substrate 10 in forming the opening 44 in the ONO film 16. In addition, the opening 44 in the ONO film 16 is formed by etching the ONO film 16, with the word line 20 and the first sidewalls 24 formed on the sides thereof used as the mask. Accordingly, it is only necessary to implement one exposure process for forming the contact hole 40. This enables the distance between the word lines 20 to be downsized and the fabrication process to be simplified.

In this manner, in accordance with the fourth embodiment, the reliability is improved by preventing charge loss from the trapping layer. It is possible to provide a flash memory in which leakage current between the bit lines can be prevented and the distance between the word lines 20 can be downsized.

As described in the fourth embodiment, the trench isolation region 50 is interposed between the bit lines 14 and isolates the elements provided below the opening 44 in the ONO film 16. Such trench isolation region 50 is applicable to the case where the second sidewalls 26 are not provided as in the first embodiment, yet the same effect is obtainable.

FIG. 30 is a cross-sectional view in forming the contact hole 40 in a variation example in accordance with the fourth embodiment. In this variation example, the first sidewall is made up of a silicon oxide layer 27 and a silicon nitride film 28. The silicon oxide layer 27 is formed on the side of the word line 20 and on the ONO film 16 (in other words, the silicon oxide layer 27 is in contact with the word line 20 and the ONO film 16). The silicon nitride film 28 is in contact with the silicon oxide layer 27. Other configurations of the variation example in accordance with the fourth embodiment are the same as those in FIG. 26 in accordance with the fourth embodiment.

Preferably, the metal silicide 22 is formed on the word line 20 subsequent to the formation of the first sidewalls. If the metal silicide 22 is formed prior to the formation of the first sidewalls, the sides of the word line 20 are also silicided. Also, if the metal silicide 22 is formed subsequent to the formation of the second sidewalls, the semiconductor substrate 10 provided below the opening 44 in the ONO film 16 is also silicided. On the other hand, it is preferable that a silicon nitride film should be employed for the insulation film to not be silicided, in forming the metal silicide 22. Accordingly, it is preferable that a silicon nitride film should be employed for the surfaces of the first sidewalls.

However, if the silicon nitride film is employed for the first sidewall, the large stress easily causes peel-off during the thermal process. So, in this variation example, the silicon nitride film 28 is formed on the surface of the first sidewalls and the silicon oxide layer 27 is formed between the word line 20 and the ONO film as a buffer layer. This makes it possible to provide a semiconductor device in which the surface of the first sidewall is difficult to be silicided or to be peeled off by stress.

This variation example is applicable to the first through third embodiments of the present invention, and the same effect is obtainable. In addition, in the first through fourth embodiments, the metal silicide 22 is provided on the word line 20 to reduce the resistance of the word line, yet it is not necessary to provide it.

Although a few preferred embodiments of the present invention have been shown and described it would be appreciated by those skilled in the art that changes may be made in these embodiments without departing from the principles and spirit of the invention, the scope of which is defined in the claims and their equivalents. For example, it is possible to apply the present invention to any other floating-gate flash memories in addition to NOR-type floating-gate flash memories, Metal Oxide Nitride Oxide Silicon (MONOS)-type and Silicon Oxide Nitride Oxide Silicon (SONOS)-type flash memories.

What is claimed is:

1. A semiconductor device comprising:
a semiconductor substrate having a bit line;
an ONO film that is provided on the semiconductor substrate and has an opening;
an interlayer insulating film that is provided on the ONO film and has a contact hole connected to the bit line and provided in the opening; and
an insulation layer provided between and separating the ONO film and the contact hole.

2. The semiconductor device as claimed in claim 1, wherein the insulation layer is a portion of the interlayer insulating film.

3. The semiconductor device as claimed in claim 1, wherein the opening formed in the ONO film is provided common to multiple bit lines.

4. The semiconductor device as claimed in claim 1, wherein the opening formed in the ONO film is provided for each bit line.

5. The semiconductor device as claimed in claim 1, further comprising a first sidewall layer that is provided on the ONO film and contacts a side of a word line provided on the ONO film, wherein the opening in the ONO film is formed with a mask composed of the word line and the first sidewall layer.

6. The semiconductor device as claimed in claim 5, wherein the first sidewall layer comprises a silicon oxide film contacting the word line and the ONO film, and a silicon nitride film contacting the silicon oxide film.

7. The semiconductor device as claimed in claim 1, further comprising a second sidewall layer provided on a side of the opening.

8. The semiconductor device as claimed in claim 7, wherein the second sidewall layer includes a silicon nitride layer.

9. The semiconductor device as claimed in claim 7, wherein the insulation layer includes the interlayer insulating layer and the second sidewall layer.

10. The semiconductor device as claimed in claim 1, further comprising a trench isolation region interposed between adjacent bit lines and provided in the opening.

11. A method of fabricating a semiconductor device comprising the steps of:
forming a bit line in a semiconductor substrate;
forming an ONO film on the semiconductor substrate;
forming an opening in the ONO film;
forming an interlayer insulating layer on the ONO film; and
forming a contact hole connected to the bit line in the interlayer insulating film and the ONO film,
wherein the step of forming the contact hole separates the ONO film from the contact hole so that an insulation film remains between the ONO film and the contact hole.

12. The method as claimed in claim 11, wherein the step of forming the opening in the ONO film comprises a step of partially removing the ONO film with a mask composed of a word line provided on the ONO film and a first sidewall layer provided on a side of the word line.

13. The method as claimed in claim 11, wherein the step of forming the opening in the ONO film forms the opening above the bit line.

14. The method as claimed in claim 11, further comprising a step of forming a second sidewall layer on a side of the opening.

15. The method as claimed in claim 11, further comprising a step of forming a trench isolation region in the semiconductor substrate prior to the step of forming the bit line, the trench isolation region being interposed between adjacent bit lines and provided in the opening in the ONO film.
